(19) United States
(12) Patent Application Publication
(10) Pub. No.: US 2004/0106273 A1
(43) Pub. Date: Jun. 3, 2004

(54) Interconnect structure and method for manufacturing the same

(75) Inventors: Ming-Shi Yeh, Chang-Hua (TW); Chiung-Sheng Hsiung, Hsin-Chu (TW); Yao-Chin Cheng, Hsin-Chu (TW)

Correspondence Address: MERCHANT & GOULD PC, P.O. BOX 2903, MINNEAPOLIS, MN, 55402-0903, US

(73) Assignee: UNITED MICROELECTRONICS CORP., Hsin-Chu (TW)

(21) Appl. No.: 10/449,459

(22) Filed: May 30, 2003

Related U.S. Application Data
(62) Division of application No. 10/308,239, filed on Dec. 2, 2002.

(51) Int. Cl. H01L 21/20

(52) U.S. Cl. 438/584

(57) ABSTRACT

A interconnect structure and the method for fabricating the same is disclosed in this present invention. By employing a metallic compound layer, the adhesion of the cap layer to the metal layer according to this invention can be improved, and metal migration due to thermal stress in the prior art will not occur in the interconnect structure according to this invention. Furthermore, the interconnect structure and the method for manufacturing the same can efficiently keep the interconnect structure from occurring metal migration, thus no voids from thermal stress will be formed in the interconnect structure. Hence, this invention can prevent the interconnect structure from raising the resistance of the interconnect structure by the voids, and efficiently improve the reliability of the interconnect in a semiconductor structure.

### BACKGROUND OF THE INVENTION

1. Field of the Invention

This present invention relates to a semiconductor structure, and more particularly, to an interconnect structure and the method for manufacturing the same.

2. Description of the Prior Art

Interconnect plays an important role in a semiconductor structure. Interconnect is employed for connecting many semiconductor devices. However, in interconnect technology, especially for some materials with high coefficient of thermal expansion (CTE), thermal stress due to the CTE mismatch between the metal layer and the dielectric layer is the major challenge for the reliability of the interconnect. During the thermal process after the formation of the interconnect, such as chemical vapor deposition, baking, or the like thermal process, the metal migration in the interconnect structure will be induced along the interface of the cap layer and the metal layer and the voids are formed in the above-mentioned interconnect structure.

For example, FIG. 1 depicts an interconnect structure with copper metal layer and low-K dielectric layer. The low-K dielectric layer 100 comprises a via. A conformal barrier layer 110 is formed in the via, and a copper metal layer 120 is filled into the via. A cap layer 140 is formed onto the copper metal layer 120. After the formation of the interconnect structure, the copper metal layer 120 is completely matched with the cap layer 140. In other words, there is no void between the copper metal layer 120 and the cap layer 140. Nevertheless, during the thermal process after the formation of the above-mentioned interconnect structure, the compressive stress due to the thermal process will enhance copper migration along the interface of the cap layer 140 and the copper metal layer 120, thus the voids 130 will be formed between the copper metal layer 120 and the cap layer 140. In a semiconductor structure, the reliability of the interconnect may be decreased by the voids 130. Moreover, the resistant of the interconnect may be increased by the voids 130, and the efficiency of the interconnect is damaged.

Hence, for improving the efficiency of an interconnect and retaining the reliability of the interconnect, it is an important object to provide a structure without the voids from metal migration in the interconnect structure and the method for manufacturing the same.

### SUMMARY OF THE INVENTION

In accordance with the present invention, a metallic compound layer is provided for improving the adhesion of the cap layer to the metal layer in a interconnect structure according to this invention, so that the interconnect structure can be prevented from metal migration in the prior art.

It is another object of this invention to improve the reliability of the interconnect structure by utilizing a metallic compound layer to keep the interconnect structure from metal migration.

It is still another object of this present invention to prevent the voids from thermal stress in the interconnect structure by employing a metallic compound layer, and thus the resistance will not be increased by the voids in the interconnect structure.

In accordance with the above-mentioned objects, the invention provides an interconnect structure and the method for manufacturing the same. According to this prevent invention, a metallic compound layer is utilized to improve the adhesion of the cap layer to the metal layer in the interconnect structure. Because the natural of the metallic compound layer is closer to the metal layer than the cap layer, the metallic compound layer can efficiently improve the adhesion of the cap layer to the metal layer and keep the interconnect structure from metal migration. Therefore, according to this invention, it is efficiently for improving the reliability of the interconnect structure and keeping the interconnect structure from increasing the resistance of the interconnect structure due to the voids in the interconnect structure.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1 is a diagram showing a interconnect structure according to the prior art;

FIG. 2 is a flow chart for manufacturing a interconnect structure according to this presented invention;

FIG. 3A is a diagram of a interconnect structure according to this present embodiment; and

FIG. 3B is another diagram of a interconnect structure according to this present embodiment.

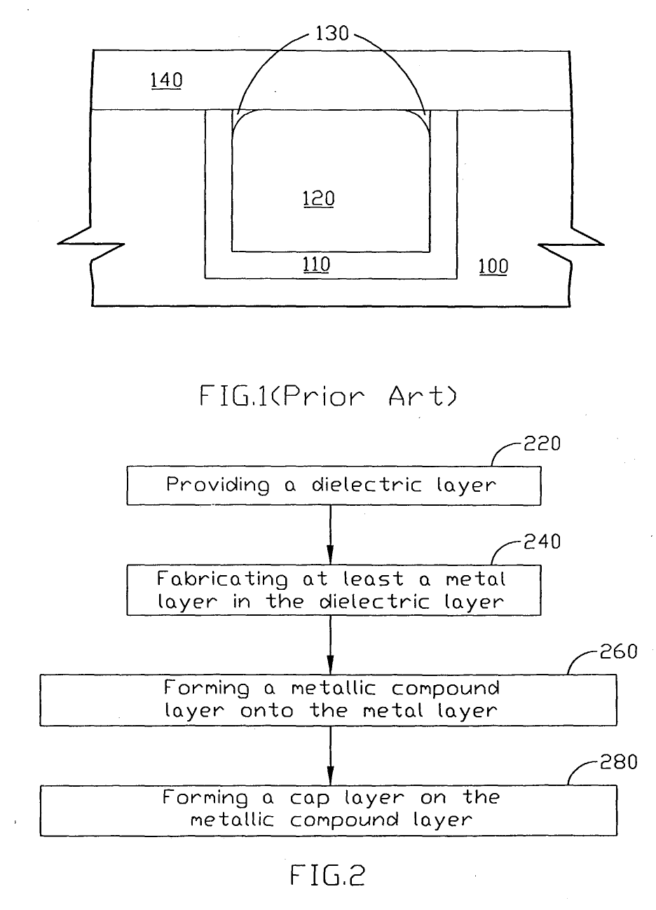

### DESCRIPTION OF THE PREFERRED EMBODIMENTS

Some sample embodiments of the invention will now be described in greater detail. Nevertheless, it should be recognized that the present invention can be practiced in a wide range of other embodiments besides those explicitly described, and the scope of the present invention is expressly not limited except as specified in the accompanying claims.

Then, the components of the semiconductor devices are not shown to scale. Some dimensions are exaggerated to the related components to provide a more clear description and comprehension of the present invention.

One preferred embodiment of this invention is a interconnect structure. The interconnect structure according in this embodiment comprises a dielectric layer, at least one metal layer in the dielectric layer, a metallic compound layer onto the metal layer, and a cap layer onto the metallic compound layer. The metal layer may be copper, or the like metal/alloy materials wherein the materials may migrate under the thermal stress between the interconnect layer and the dielectric layer and under the high temperature. The dielectric layer may be a low-K dielectric layer.

In this present embodiment, the metallic compound layer may be CoWP, CoWB, or other metallic compounds. In contrast with the interconnect structure in the prior art, the above-mentioned metallic compound layer has much better adhesion to the metal layer than the traditional cap layer. Therefore, the metallic compound layer between the metal layer and the cap layer is good for increasing the adhesion of the metal layer and the cap layer. Thus the metal migration issue in the interconnect structure in the prior art can be eliminated.

Besides, the interconnect structure according to this embodiment may further comprise a single damascene structure or a dual damascene structure on the cap layer. In other words, the interconnect structure may comprise a second dielectric layer on the above-mentioned on the cap layer, at least one second metal layer in the second dielectric layer, and so on.

Another preferred embodiment of this present invention is a method for manufacturing a interconnect structure. FIG. 2 is a flowchart showing the method for manufacturing a interconnect structure according to this embodiment. At first, a dielectric layer is provided on a substrate, as the step 220. The dielectric layer may be formed by a deposition process, or other technology in the prior art. The above-mentioned substrate comprises a plurality of semiconductor device. In step 240, at least a metal layer is formed in the dielectric layer. The above-mentioned metal layer may be formed by an etching process for fabricating at least a via in the dielectric layer and a depositing process for filling the via with metal materials. In order to prevent the diffusion of the metal layer to the dielectric layer, the method according to this embodiment may further comprise a step for forming a conformal barrier layer in the above-mentioned via before the deposition process for filling the via with the metal materials. The metal layer may be copper, or other metal/alloy materials. The conformal barrier layer is consisted of Ta, TaN, or other materials used in the prior art.

Subsequently, a metallic compound layer is formed onto the metal layer, as shown in the step 260. The metallic compound layer may be a layer onto the dielectric layer and the metal layer, or a layer selected onto the metal layer. The metallic compound layer may be formed by electroless process, chemical vapor deposition, physical vapor deposition process, or other original technologies. The metallic compound layer includes CoWP, CoWB, or other metallic materials. The thickness of the metallic compound layer may be 25 to 500 angstrom. Finally, as shown in the step 280, a cap layer is formed onto the metallic compound layer and the dielectric layer. The cap layer may be formed by a well-known process in the prior art, such as chemical vapor deposition, and so on. The cap layer may be SiN, SiC, or other materials employed in the cap layer in the prior art.

In this manner, due to the metallic compound layer between the metal layer and the cap layer, the interconnect structure fabricated by the method according to this embodiment can be kept from the metal migration issue in the prior art. The natural of the metallic compound layer is closer to the natural of the metal layer than the cap layer. That is, because of the formation of the metallic compound layer, the adhesion of the metal layer to the cap layer according to this embodiment is better than the cap layer in the prior art. Thus, the metal migration issue in the prior art can be eliminated in the interconnect structure according to this embodiment.

In addition, the method according to this embodiment may further comprise other steps for fabricating the semiconductor devices on the cap layer of the above-mentioned interconnect structure. For instance, following the formation of the above-mentioned interconnect structure, one continue dual damascene process may be performed. That is, after forming the cap layer, a second dielectric layer, referred to the above-mentioned dielectric layer as the first dielectric layer, is fabricated onto the cap layer. The second dielectric layer also may be formed by chemical vapor deposition, or the like original process. Subsequently, an etching process is performed for fabricating at least a second via, referred to the above-mentioned via as the first via, through the second dielectric layer, the cap layer, and the metallic compound layer to expose the (first) metal layer. A second conformal barrier layer is fabricated in the second via. Finally, a second metal layer is filled into the second via. The second metal layer is consisted of copper, aluminum, or other metal/alloy materials.

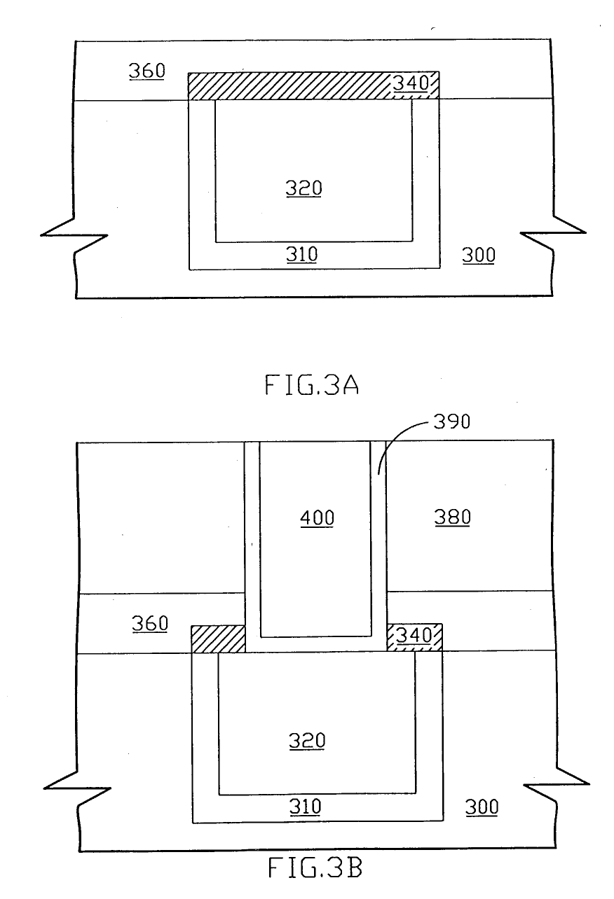

Another preferred embodiment according to this present invention is a interconnect structure. FIG. 3A depicts a interconnect structure according to this embodiment. Referred to FIG. 3A, the above-mentioned interconnect structure comprises a first dielectric layer 300, a first metal layer 320 in the first dielectric layer 300, a metallic compound layer 340 onto the first metal layer 320, and a cap layer 360 onto the first dielectric layer 300 and the metallic compound layer 340. The first dielectric layer 300 may be a low-K dielectric layer, wherein the dielectric constant of the low-K dielectric layer is lower than 4.

The first dielectric layer 300 comprises at least a first via, and the first metal layer 320 is in the first via. The first metal layer 320 may be fabricated by an etching process for forming the first via in the first dielectric layer 300 and a depositing process for filling the first via. The first metal layer 320 may be copper, or other well-known metal or alloy materials employed as interconnect in the semiconductor manufacture. In order to prevent the diffusion of the first metal layer 320 into the first dielectric layer 300, the interconnect structure according to this embodiment further comprises a first conformal barrier layer 310 in the first via. The first conformal barrier layer 310 is consisted of TaN, Ta, or the like materials.

The metallic compound layer 340 may be only onto the first metal layer 320, as shown in FIG. 3A. The metallic compound layer 340 also may be onto the first dielectric layer 300 and the first metal layer 320. The metallic compound layer 340 includes CoWP, CoWB, or other metallic compounds. Moreover, the metallic compound layer 340 may be formed by electroless process, chemical vapor deposition, physical vapor deposition, or other technologies. In this present embodiment, the thickness of the metallic compound layer 340 may be 25 to 500 angstrom. The cap layer 360 onto the first dielectric layer 300 and the metallic compound layer 340 is made of SiN, SiC, or other materials. As the cap layer in the prior art, the cap layer 360 may be formed by deposition process, or other original process.

The natural of the metallic compound layer 340 is closer to the first metal layer 320 than the cap layer 360, and the metallic compound layer 340 has better adhesion to the first metal layer 320 than the cap layer. In other words, compared with the interconnect structure in the prior art, because the metallic compound layer 340 is between the first metal layer 320 and the cap layer 360, the adhesion of the cap layer 360 to the first metal layer 320 through the metallic compound layer 340 is better than the cap layer in the prior art. The interconnect structure according to this embodiment can prevent the metal migration issue in the prior art, and keep the interconnect structure from forming the voids due to the thermal stress. Therefore, the reliability of the above-mentioned interconnect structure can be improved, and the resistance of the interconnect structure will not be raised.

Referred to FIG. 3B, the interconnect structure according to this embodiment may further comprises a second dielectric layer 380 onto the cap layer 360, and at least a second metal layer 400 in the second dielectric layer 380. At least a second via is in the second dielectric layer 380, and through the second dielectric layer 380, the cap layer 360, and the metallic compound layer 340 to expose the first metal layer 320. A second conformal barrier layer 390 is fabricated in the second via, and the second metal layer 400 is filled into the second via. The second conformal barrier layer 390 is employed to prevent the diffusion of the second metal layer 400 to the second dielectric layer 380. The component of the second metal layer 400 includes copper, aluminum, or other metal or alloy materials.

According to the preferred embodiments, this invention discloses a interconnect structure for preventing metal migration and the method for manufacturing the same. In this present invention, the interconnect structure comprises a dielectric layer, at least a metal layer in the dielectric layer, a metallic compound layer onto the metal layer, and a cap layer onto the metallic compound layer. The natural of the metallic compound layer is closer to the metal layer than the cap layer, thus the adhesion of the cap layer, with a metallic compound layer between the cap layer and the metal layer, to the metal layer is better than the cap layer in the prior art. Therefore, the interconnect structure according to this present invention can efficiently prevent metal migration in the prior art. Moreover, in this invention, a method for manufacturing the above-mentioned interconnect structure is disclosed. The method comprises the steps of providing a dielectric layer, fabricating at least a metal layer in the dielectric layer, forming a metallic compound layer onto the metal layer, and forming a cap layer onto the metallic compound layer. The entire above-mentioned element in the interconnect structure according to the method may be formed by any well-known process of the one original in this art. Furthermore, the above-mentioned interconnect structure can efficiently prevent metal migration in the prior art. Hence, the interconnect structure and the method for manufacturing the same can efficiently prevent voids from thermal stress in the interconnect structure, and the reliability of the interconnect structure will be improved.

Although specific embodiments have been illustrated and described, it will be obvious to those skilled in the art that various modifications may be made without departing from what is intended to be limited solely by the appended claims.

What is claimed is:

1. A interconnect structure, comprising:
a first dielectric layer;
a first metal layer in said first dielectric layer;
a metallic compound layer onto said first metal layer; and
a cap layer onto said metallic compound layer.

2. The structure according to claim 1, wherein said first dielectric layer comprises a low-K dielectric material.

3. The structure according to claim 1, wherein said first metal layer comprises copper.

4. The structure according to claim 1, wherein said metallic compound layer is formed by electroless process.

5. The structure according to claim 1, wherein said metallic compound layer is formed by deposition process.

6. The structure according to claim 1, further comprises:
a second dielectric layer onto said cap layer; and
a second metal layer in said second dielectric layer.

7. The structure according to claim 1, wherein said cap layer includes a dielectric material.

8. A interconnect structure, comprising:
a first dielectric layer with at least a first via;
a conformal barrier layer in said first via;
a first metal layer filled in said first via;
a metallic compound layer onto said first metallic layer; and
a cap layer onto said metallic compound layer.

9. The structure according to claim 8, wherein said first dielectric layer includes a low-K dielectric material.

10. The structure according to claim 8, wherein said first metal layer comprises copper.

11. The structure according to claim 8, wherein said metallic compound layer is CoWP.

12. The structure according to claim 8, wherein said metallic compound layer is CoWB.

13. The structure according to claim 8, further comprises:
a second dielectric layer onto said cap layer, wherein said second dielectric layer comprises at least a second via; and
a second metal layer in said second via.

14. A method for fabricating a interconnect structure, comprising:
providing a first dielectric layer with at least a first via;
filling a first metal layer into said first via;
fabricating a metallic compound layer onto said first metal layer; and
forming a cap layer onto said metallic compound layer.

15. The method according to claim 14, further comprises:
forming a second dielectric layer onto said cap layer, wherein said second dielectric layer comprises at least a second via; and
filling a second metal layer into said second via.

16. The method according to claim 14, before said step for filling said first metal layer, further comprises a step for forming a conformal barrier layer in said first via.

17. The method according to claim 14, wherein said first dielectric layer comprises a low-K dielectric material.

18. The method according to claim 14, wherein said first metal layer comprises copper.

19. The method according to claim 14, wherein said metallic compound layer is formed by electroless process.

20. The method according to claim 14, wherein said step for fabricating said metallic compound layer comprises a deposition process.

21. The method according to claim 14, wherein said metallic compound layer comprises CoWP.

22. The method according to claim 14, wherein said metallic compound layer comprises CoWB.

23. The structure according to claim 14, wherein said cap layer includes a dielectric material.
